(19) United States
(12) Patent Application Publication
(10) Pub. No.: US 2025/0196677 A1
(43) Pub. Date: Jun. 19, 2025

(54) POWER CONVERSION ELECTRONIC APPLIANCE FOR ELECTRIC OR HYBRID VEHICLES

(71) Applicant: META SYSTEM S.P.A., REGGIO EMILIA (RE) (IT)

(72) Inventor: Cesare LASAGNI, REGGIO EMILIA (RE) (IT)

(21) Appl. No.: 18/847,449

(22) PCT Filed: Mar. 14, 2023
(86) PCT No.: PCT/IB2023/052471

§ 371 Date: Sep. 16, 2024

(30) Foreign Application Priority Data
Mar. 17, 2022 (IT) 102022000005288

(51) Int. Cl. B60L 53/22; B60L 50/64; H01M 10/46; H01M 10/613; H01M 10/625; H01M 10/653; H01M 10/6551; H01M 50/249; H02J 7/00; H02M 3/00; H05K 7/20

(52) U.S. Cl. CPC B60L 53/22; B60L 50/64; H01M 10/46; H01M 10/613; H01M 10/625; H01M 10/653; H01M 10/6551; H01M 50/249; H02M 3/003; H05K 7/209; B60L 2210/10; H01M 2220/20; H02J 7/0042

(57) ABSTRACT

The power conversion electronic appliance (1) for electric or hybrid vehicles, installable within at least one electric or hybrid vehicle and connectable to at least one battery of said vehicle, comprises: an external container (2); an electronic circuit (3) housed in said container (2) which is connectable to the battery and comprises a plurality of electrical components (4) configured for the conversion of an input current/voltage into a predefined output current/voltage to be sent to the battery; and at least one cover (5) intended to close the container (2) at the top; at least one layer (6), positioned between the electrical components (4) and the cover (5) and made of an elastically deformable material which is arranged in contact with each of the electrical components (4) and is adapted to damp the vibrations transmitted by the electrical vehicle to the electrical components (4).

### TECHNICAL FIELD

The present invention relates to a power conversion electronic appliance for electric or hybrid vehicles of the type of a battery charger (so-called “on-board chargers”, OBCs) or a DC-DC converter that can be installed on an electric or hybrid vehicle and connectable to the vehicle's electric battery.

### BACKGROUND ART

As is well known, electric and hybrid vehicles are provided with power electronic appliances, such as battery chargers (so-called “on-board chargers”, OBCs) or DC-DC converters, provided with special electrical components (particularly of the type of electrolytic and/or film capacitors) adapted to carry out the conversion of an input voltage/current into a corresponding and predefined output voltage/current.

With reference to such electrical components, there is nowadays an increasing need to reduce the stresses experienced by the latter during their operational life in order to preserve, for as long as possible, their structural integrity and consequent functionality.

In this regard, it is well known how the vibrations generated when the vehicle is in motion and consequently transmitted to the electrical components cause stresses on the latter that end up, in the long run, damaging them and causing premature end of life.

To cope, at least partly, with this problem, technical solutions are known that consist of applying glue drops (e.g., of the silicone adhesive type) between one electrical component and another.

In fact, the glue applied in this way makes it possible to dampen the vibrations transmitted from the electric vehicle to the electrical components and, consequently, to at least partly reduce the stresses experienced by the latter when the vehicle is in motion.

In this way, it is, therefore, possible to preserve the structural integrity of the electrical components for longer and extend their operating life.

Nevertheless, the technical solution just described is not without its drawbacks. First, it should be kept in mind that power conversion electronic appliances can comprise an extremely large number of electrical components within it.

This implies that the amount of glue that needs to be applied between electrical components can be just as high.

Not only that, but the application of such quantities of glue inevitably requires rather long working times, which end up negatively affecting the appliance production volumes.

This very fact results in, among other things, increases on the selling price of the appliances.

### DESCRIPTION OF THE INVENTION

The main aim of the present invention is to devise a power conversion electronic appliance for electric or hybrid vehicles which can reduce the mechanical stresses experienced by the electrical components due to vibration while the vehicle is in motion while simultaneously lowering the production time and associated sale costs compared with the prior art.

Another object of the present invention is to devise a power conversion electronic appliance for electric or hybrid vehicles which can overcome the aforementioned drawbacks of the prior art within the framework of a simple, rational, easy and effective to use as well as cost-effective solution.

The aforementioned objects are achieved by this power conversion electronic appliance for electric or hybrid vehicles having the characteristics of claim 1.

### BRIEF DESCRIPTION OF THE DRAWINGS

Other characteristics and advantages of the present invention will become more apparent from the description of a preferred, but not exclusive, embodiment of a power conversion electronic appliance for electric or hybrid vehicles, illustrated by way of an indicative, yet non-limiting example, in the accompanying tables of drawings in which:

FIGS. 1 and 2 are axonometric, exploded views of the appliance according to the invention.

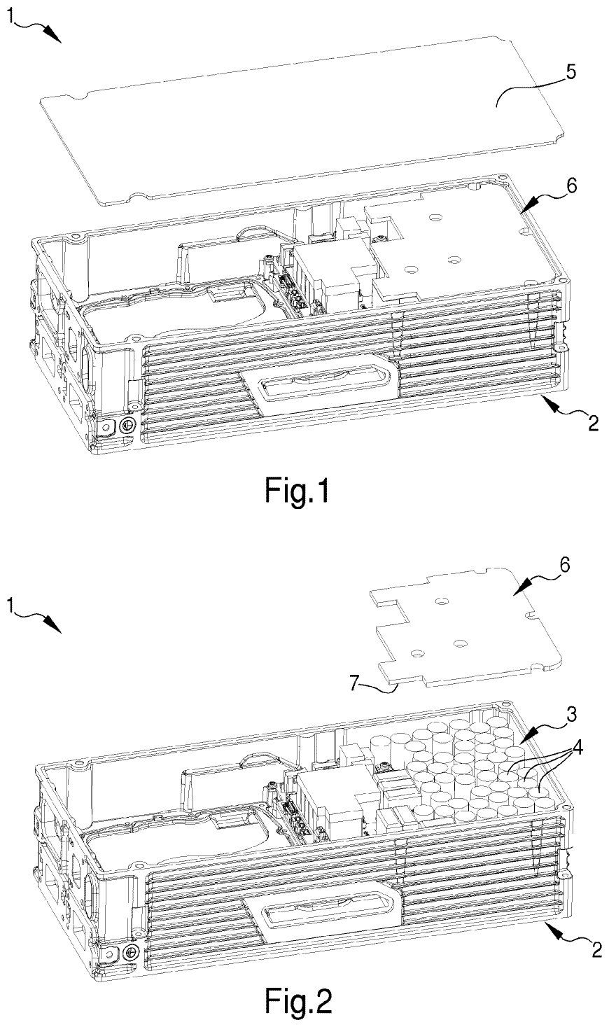

### EMBODIMENTS OF THE INVENTION

With particular reference to these figures, reference numeral 1 globally indicates a power conversion electronic appliance for electric or hybrid vehicles.

According to one possible embodiment, the appliance 1 consists of a battery charger or on board charger (“OBC”) which can be installed on an electric or hybrid vehicle and connected to the vehicle's electric battery.

Alternatively, according to another possible embodiment, the appliance 1 consists of a DC/DC converter which can be installed on an electric or hybrid vehicle and connected to the vehicle's electric battery.

In all cases, the power conversion electronic appliance 1 for electric or hybrid vehicles, which can be installed inside at least one electric or hybrid vehicle and can be connected to at least one battery of the vehicle, comprises:
at least one external container 2;
at least one electronic circuit 3 housed in the container 2 which is connectable to the battery and comprises a plurality of electrical components 4 (particularly of the type of electrolytic and/or film capacitors) configured for the conversion of an input current/voltage into a predefined output current/voltage to be sent to the battery; and
at least one cover 5 intended to close the container 2 at the top.

Specifically, the electronic circuit 3 comprises one or more power electronic boards provided with power components (e.g. of the active semiconductor type) and with electrical components 4.

In the present case, the electronic control boards allow carrying out the adjustment of various power components and/or electrical components 4 e.g. depending on the input current/voltage into the appliance 1.

The power and control electronic boards are, in particular, of the type conventionally used in OBC chargers or DC-DC converters which can be installed in an electric or hybrid vehicle.

According to the invention, the appliance 1 comprises, positioned between the electrical components 4 and the cover 5, at least one layer 6 which is arranged in contact with each of the electrical components 4.

In actual facts, the layer 6 is placed on top of the various electrical components 4 and is, precisely, positioned between the top of the latter and the lower face (i.e., the one facing the inside of the container 2) of the cover 5.

In detail, the layer 6 is adapted to dampen the vibrations transmitted by the electrical vehicle to the electrical components 4.

In this sense, the layer 6 is made at least partly of an elastically deformable material.

Specifically, the layer 6 is of the type of a sponge.

Importantly, the choice of making the layer 6 of an elastically deformable material proves to be particularly advantageous in this circumstance.

Due to this feature, in fact, the crushing of the layer 6 induced by closing the cover 5 causes the layer itself, elastically deforming, to be pushed between one component 4 and the other.

This makes it possible to increase the contact surface area between the layer 6 and the electrical components 4 and, as a clear and direct consequence, to dampen even more effectively the vibrations handed down to the latter.

To further reduce the stresses experienced by the electrical components 4, the layer 6 is conveniently provided with at least one adhesive side 7 which faces the electrical components 4 and is associated with the latter in an adhesive manner.

In actual facts, the layer 6 is glued on top of the electrical components 4 by means of the adhesive side 7.

As anticipated, the bonding of the adhesive side 7 on the electrical components 4 operates synergistically in conjunction with the elastically deformable material of which the layer 6 is made in ensuring a drastic reduction in the stresses experienced by the electrical components 4.

In fact, the bonding pressure created between the layer 6 and the electrical components 4 makes it possible to dissipate most of the vibrations transmitted to the latter, reducing them in intensity and thus averting any harmful effects on the electrical components themselves.

Describing these advantages, it should be added that the layer 6 is preferably made, at least partly, of an electrically insulating material.

It must be remembered, in this regard, that the electrical components 4 work at high voltages and, therefore, sufficient space must be left between them and the cover 5 to avert the risk of electrical conduction between the two and the consequent danger to the safety of vehicle passengers. 5

Although justified by this reason, this fact results in an inconvenient increase in the overall dimensions of the appliance 1, which can, at times, end up complicating the installation of the latter in the vehicles (e.g., in the case of vehicles provided with reduced space in which to arrange the appliance 1).

Keeping all this in mind, it is easy to appreciate that by providing a layer 6 made of elastically deformable and electrically insulating material makes it possible both to reduce the overall dimensions of the appliance 1 (by crushing the layer 6 and pushing it between the various electrical components 4 by closing the cover 5) and to ensure, at the same time, the complete electrical insulation of the appliance 1.

According to a first embodiment, the layer 6 is made at least partly of at least one thermally conductive material.

Thus, the layer 6 can be profitably used not only to reduce the stresses experienced by the electrical components 4 due to vibration, but also to effectively dissipate the heat that the electrical components themselves produce when in operation.

In more detail, the layer 6 according to this first embodiment is entirely made of the thermally conductive material.

According to a second embodiment, an alternative to the previous one, the layer 6 comprises a plurality of heat dissipation openings, not shown in the figures for simplicity sake.

Specifically, each of the openings is located at the point where a respective electrical component 4 is located and is filled at least partly with at least one thermally conductive material.

In actual facts, in this second embodiment the thermally conductive material is present only inside the openings and, therefore, only at the point where the electrical components 4 are located.

It is easy to appreciate how the embodiment just described enables the effective dissipation of heat generated by the electrical components 4 using a reduced amount of thermally conductive material to do so.

In this way, it is clearly possible to reduce the manufacturing cost of the layer 6 and the resulting retail price of the appliance 1.

Openings can be obtained by means of die-cutting the layer 6, or by different technological processes that allow, in all cases, obtaining openings that can be filled at least partly with the thermally conductive material.

In this regard, the thermally conductive material is preferably of the type of a thermally conductive foam, but still it cannot be ruled out that it may be, at least partly, of different types known to the expert in the field.

It has in practice been ascertained that the described invention achieves the intended objects.

In particular, the fact is emphasized that the special expedient of providing an elastically deformable layer arranged in contact with each of the components makes it possible to effectively dampen the vibrations transmitted by the vehicle in motion to the components, thereby reducing the stresses experienced by the latter and increasing, in this way, their operating life.

1. Power conversion electronic appliance (1) for electric or hybrid vehicles, installable within at least one electric or hybrid vehicle and connectable to at least one battery of said vehicle, comprising:
at least one external container (2);
at least one electronic circuit (3) housed in said container (2) which is connectable to said battery and comprises a plurality of electrical components (4) configured for the conversion of an input current/voltage into a predefined output current/voltage to be sent to said battery; and
at least one cover (5) intended to close said container (2) at the top;
characterized by the fact that it comprises, positioned between said electrical components (4) and said cover (5), at least one layer (6) made at least partly of an elastically deformable material which is arranged in contact with each of said electrical components (4) and is adapted to damp the vibrations transmitted by said electrical vehicle to said electrical components (4).

2. Appliance (1) according to claim 1, characterized by the fact that said layer (6) is made at least partly of an electrically insulating material.

3. Appliance (1) according to claim 1, characterized by the fact that said layer (6) is provided with at least one adhesive side (7) which faces said electrical components (4) and is associated with the latter in an adhesive manner.

4. Appliance (1) according to claim 1, characterized by the fact that said layer (6) is made at least partly of at least one thermally conductive material.

5. Appliance (1) according to claim 1, characterized by the fact that said layer (6) comprises a plurality of heat dissipation openings, each of said openings being located at the point where a respective said electrical component (4) is located and being filled at least partly with at least one thermally conductive material.

6. Appliance (1) according to claim 4, characterized by the fact that said thermally conductive material is of the type of a thermally conductive foam.

7. Appliance (1) according to claim 1, characterized by the fact that said layer (6) is of the type of a sponge.

8. Appliance (1) according to claim 1, characterized by the fact that it is composed of an OBC charger.

9. Appliance (1) according to claim 1, characterized by the fact that it is composed of a DC/DC converter.
